(19) United States
(12) Patent Application Publication
(10) Pub. No.: US 2025/0234623 A1
(43) Pub. Date: Jul. 17, 2025

(54) GATE-ALL-AROUND TRANSISTOR HAVING MULTIPLE GATE LENGTHS

(71) Applicant: Taiwan Semiconductor Manufacturing Company, Ltd., Hsin-Chu (TW)

(72) Inventors: Pin Chun Shen, Changhua County (TW); Jen-Hsiang Lu, Taipei City (TW); Chia Ming Liang, Taipei (TW); Kao-Ting Lai, Hsinchu City (TW); Jhon Jhy Liaw, Hsinchu County (TW)

(21) Appl. No.: 18/656,782

(22) Filed: May 7, 2024

Related U.S. Application Data
(60) Provisional application No. 63/620,648, filed on Jan. 12, 2024.

(51) Int. Cl. H01L 29/423; H01L 29/06; H01L 29/417; H01L 29/66; H01L 29/775; H01L 29/786

(52) U.S. Cl. CPC H10D 64/518; H10D 30/014; H10D 30/43; H10D 30/6735; H10D 30/6757; H10D 62/121; H10D 64/017; H10D 64/018; H10D 64/258

(57) ABSTRACT

A semiconductor structure and a method of forming the same are provided. In an embodiment, an exemplary method includes forming a fin-shaped active region over a substrate and comprising a number of channel layers interleaved by a number of sacrificial layers, removing a source/drain region of the fin-shaped active region to form a source/drain opening, forming a source/drain feature in the source/drain opening, selectively removing the number of sacrificial layers to form a number of gate openings, and forming a gate structure in the number of gate openings, where the gate structure includes a first portion formed in a first gate opening of the number of gate openings and a second portion formed in a second gate opening of the number of gate openings, a gate length of the first portion is different from a gate length of the second portion.

### PRIORITY DATA

This application claims priority to U.S. Provisional Patent Application Ser. No. 63/620,648 filed Jan. 12, 2024, the entire disclosure of which is hereby incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices are introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. The channel region of a GAA transistor may be formed from nanowires, nanosheets, other nanostructures, and/or other suitable structures. The shapes of the channel region have also given a GAA transistor alternative names such as a nanostructure transistor, a nanosheet transistor, or a nanowire transistor. There's always a need to improve device performance of the GAA transistors.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor structure, according to one or more aspects of the present disclosure.

FIGS. 2, 3, 4, 5, 6, 7, 8, 9, 10, 11, and 12 illustrate fragmentary cross-sectional views of the semiconductor structure during various fabrication stages in the method of FIG. 1, according to one or more aspects of the present disclosure.

FIG. 13 illustrates a fragmentary cross-sectional view of a first alternative semiconductor structure, according to one or more aspects of the present disclosure.

FIG. 14 illustrates a fragmentary cross-sectional view of a second alternative semiconductor structure, according to one or more aspects of the present disclosure.

FIG. 15 illustrates a fragmentary cross-sectional view of a third alternative semiconductor structure, according to one or more aspects of the present disclosure.

FIG. 16 illustrates a fragmentary cross-sectional view of a fourth alternative semiconductor structure, according to one or more aspects of the present disclosure.

FIG. 17 illustrates a fragmentary cross-sectional view of a fifth alternative semiconductor structure, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

GAA transistors have been introduced to improve gate control by increasing gate-channel coupling, reducing off-state current, and reducing short-channel effects (SCEs). Formation of a GAA transistor includes formation of a stack that includes a number of channel layers interleaved by a number of sacrificial layers, where the sacrificial layers may be selectively removed to release the channel layers as channel members. A gate structure, which includes multiple dielectric and conductive layers, is then formed to wrap around each of the channel members. Inner spacer features are formed to isolate the gate structure from source/drain features. The portion of the channel member that is disposed directly over or under the inner spacer features is thus not covered by the gate structure and may be referred to as a source/drain extension region. Parasitic resistance associated with the source/drain extension region of the channel member may be referred to as an extension resistance Rₑₓₜ. A high extension resistance Rₑₓₜ of a bottommost channel member of the channel members may lead to poor channel usage, which degrades device performance.

The present disclosure provides GAA transistors with reduced extension resistance Rₑₓₜ and methods of forming the same. In an embodiment, a GAA transistor of the present disclosure includes a number of nanostructures and a gate structure wrapping around and over the number of nanostructures. A portion of the gate structure disposed directly under a bottommost nanostructure of the number of nanostructures has a gate length that is greater than a gate length of a portion of the gate structure disposed immediately under a topmost nanostructure of the number of nanostructures. That is, different portions of the gate structure have different gate lengths. In an embodiment, inner spacer features and gate spacers in direct contact with the different portions of the gate structure also have different widths. By forming the GAA transistor having different gate lengths, the extension resistance Rₑₓₜ of the bottommost channel member of the channel members may be reduced to improve device performance (e.g., boosted drive current) without substantially incurring penalty to other performance characteristics.

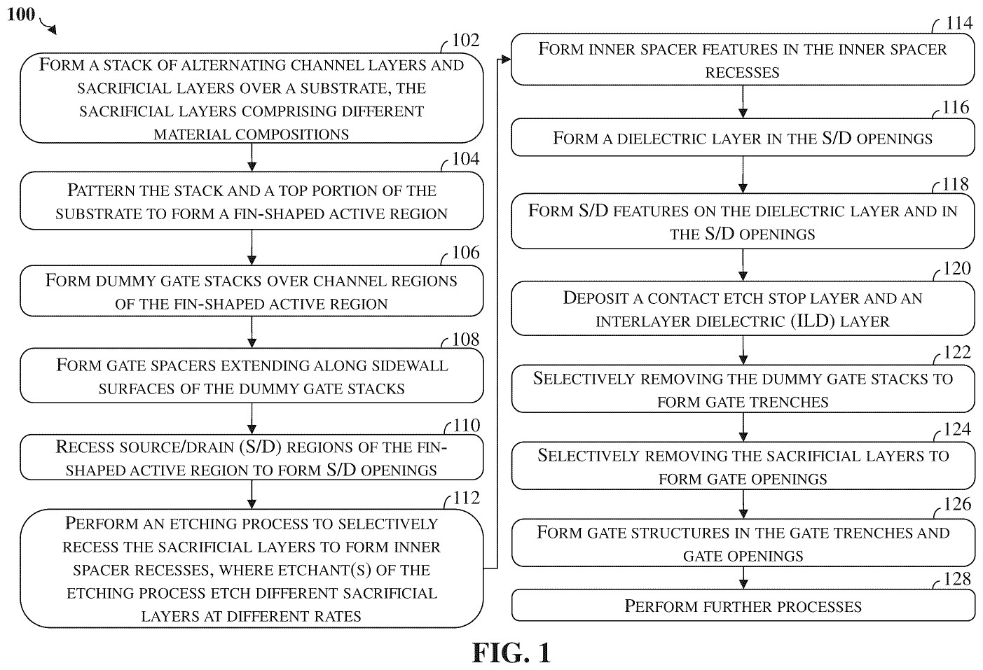

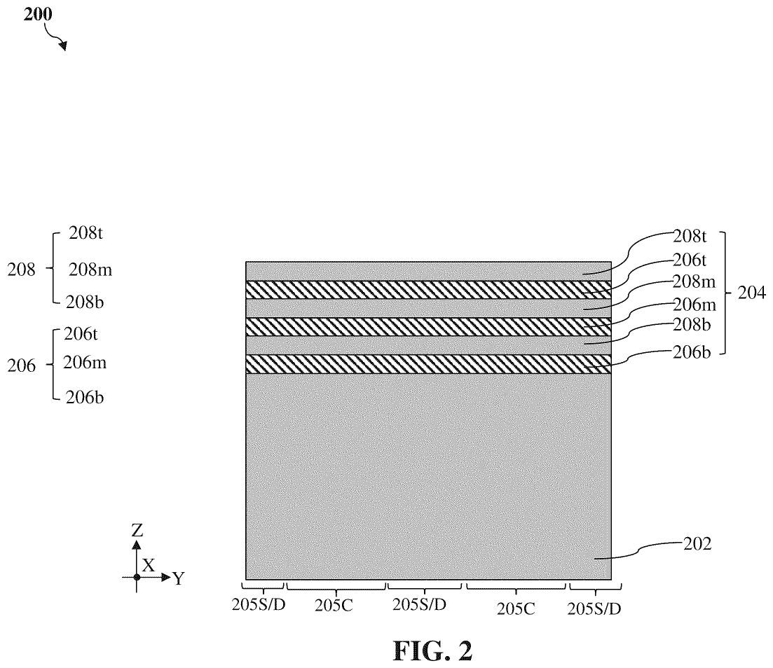

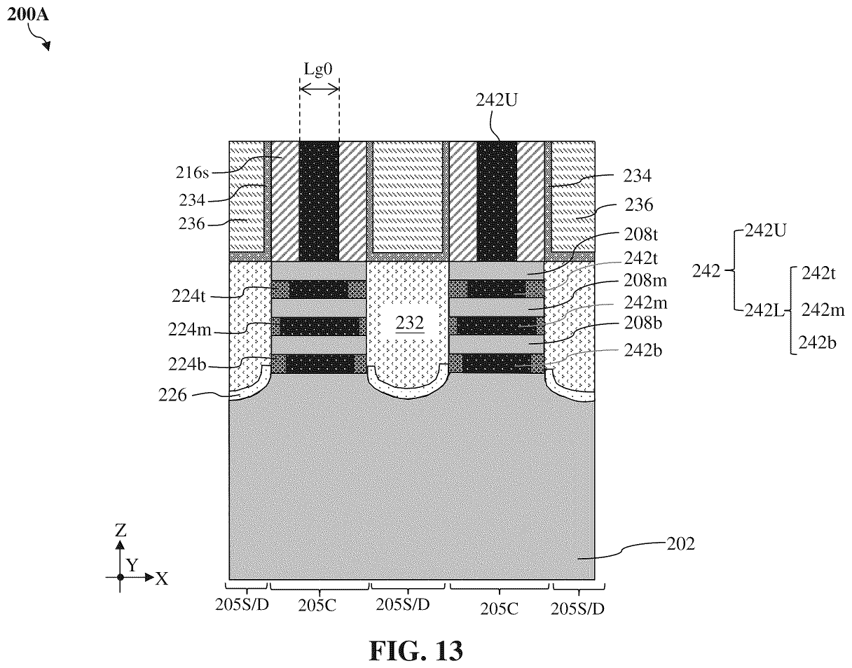

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2-12, which are fragmentary cross-sectional views of a structure 200 at different stages of fabrication in the method 100. Method 100 is merely an example and is not intended to limit the present disclosure to what is explicitly illustrated therein. Additional steps may be provided before, during, and/or after the method 100, and some steps described can be replaced, eliminated, or moved around for additional embodiments of the method. Not all steps are described herein in detail for reasons of simplicity. Because the structure 200 will be fabricated into a semiconductor structure 200 upon conclusion of the fabrication processes, the structure 200 may be referred to as the semiconductor structure 200 as the context requires. FIGS. 13-17 illustrate fragmentary cross-sectional views of alternative structures (e.g., structures 200A-200E) of the structure 200. For avoidance of doubts, the X, Y and Z directions in FIGS. 2-17 are perpendicular to one another and are used consistently throughout FIGS. 2-17. Throughout the present disclosure, like reference numerals denote like features unless otherwise excepted.

Referring to FIGS. 1 and 2, method 100 includes a block 102 where a stack 204 of alternating channel layers and sacrificial layers are formed over a substrate 202. In one embodiment, the substrate 202 is a silicon (Si) substrate. In some other embodiments, the substrate 202 may include other semiconductors such as germanium (Ge), silicon germanium (SiGe), or a III-V semiconductor material. Exemplary III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a semiconductor-on-insulator (SOI) structure. Although not explicitly shown in the figures, the substrate 202 may include an n-type well region and a p-type well region for fabrication of transistors of different conductivity types. When present, each of the n-type well and the p-type well is formed in the substrate 202 and includes a doping profile. An n-type well may include a doping profile of an n-type dopant, such as phosphorus (P) or arsenic (As). A p-type well may include a doping profile of a p-type dopant, such as boron (B). The doping in the n-type well and the p-type well may be formed using ion implantation or thermal diffusion and may be considered portions of the substrate 202.

As shown in FIG. 2, the stack 204 includes a number of sacrificial layers (e.g., 206b, 206m, 206t) and a number of channel layers (e.g., 208b, 208m, 208t) interleaved by the number of sacrificial layers. The sacrificial layers 206b, 206m, 206t may be collectively or individually referred to as the sacrificial layers 206 or the sacrificial layer 206; and the channel layers 208b, 208m, 208t may be collectively or individually referred to as the channel layers 208 or the channel layer 208. The channel layers 208 and the sacrificial layers 206 include different materials to provide etch selectivity. Each channel layer 208 may include a semiconductor material such as, for example, Si, Ge, SiC, SiGe, GeSn, SiGeSn, SiGeCSn, other suitable semiconductor materials, or combinations thereof, while each sacrificial layer 206 has a material different from that of the channel layer 208. In one such example, the channel layers 208 may include elemental Si and the sacrificial layers 206 may include SiGe. In the present embodiments, to facilitate the formation of a functional gate structure with different portions having different gate lengths to reduce the extension resistance, the sacrificial layers 206b, 206m, 206t include the same material (e.g., silicon germanium) but different constituent atomic percentages to provide desired etching selectivity. More specifically, germanium contents of the different sacrificial layers 206 are different. More specifically, a germanium concentration Ct of a topmost sacrificial layer 206t is higher than a germanium concentration Cb of the bottommost sacrificial layer 206b. A germanium concentration Cm of the middle sacrificial layer 206m may be equal to, higher than, or lower than the germanium concentration Ct. In an embodiment, Ct is equal to Cm and is higher than Cb. In another embodiment, Ct is higher than Cm, and Cm is equal to Cb. In another embodiment, Ct is higher than Cm, and Cm is higher than Cb. In another embodiment, Ct is higher than Cb, and Cb is higher than Cm.

Each of the germanium concentrations Cb, Cm, and Ct is less than 70 atomic percent (at %) and greater than 5 at %. If the germanium concentration is less than 5 at %, a prolonged etching duration may be applied to remove the sacrificial layers 206 in a subsequent channel release process, which may damage other features adjacent to the sacrificial layers. Furthermore, a low germanium content may lead to a low etch selectivity between the sacrificial layers 206 and the channel layers 208, and the sacrificial layers 206 may not be selectively removed without substantially etching the channel layers 208, leading to an increased parasitic resistance. If the germanium concentration is greater than 70%, the number of germanium that would diffuse into the channel layers 208 may increase, leading to an increased impurity concentration in the channel layers 208, thereby degrading device performance. Also, a higher concentration of germanium content in the sacrificial layers 206 may cause crystalline defects, such as dislocations. A difference between the germanium concentrations Ct and Cb is greater than 3% such that etchant(s) can etch the topmost sacrificial layer 216t and the bottommost sacrificial layer 216b at noticeable different rates. To achieve a better tradeoff among the impurity concentration, the etch selectivity between the sacrificial layers 206 and the channel layers 208, and the etch selectivity between the sacrificial layers 206t and 206b, in an embodiment, the germanium concentration Cb may be in a range between about 10 at % and 26 at %, the germanium concentration Cm and the germanium concentration Ct each may be in a range between about 21 at % and 70 at %, and Cb is lower than both Cm and Ct. In another embodiment, the germanium concentration Cb may be in a range between about 21 at % and 70 at %, the germanium concentration Cm and the germanium concentration Ct each may be in a range between about 10 at % and 26 at %, and Cb is higher than both Cm and Ct.

In some embodiments, the sacrificial layers 206 and channel layers 208 may be deposited using an epitaxial process. Suitable epitaxial processes include vapor-phase epitaxy (VPE), ultra-high vacuum chemical vapor deposition (UHV-CVD), molecular beam epitaxy (MBE), and/or other suitable processes. As shown in FIG. 2, the sacrificial layers 206 and the channel layers 208 are deposited alternatingly, one-after-another, to form the stack 204. It is noted that three layers of the sacrificial layers 206 and three layers of the channel layers 208 are alternately and vertically arranged as illustrated in FIG. 2, which are for illustrative purposes only and not intended to be limiting beyond what is specifically recited in the claims. It is understood that any number of sacrificial layers and channel layers can be formed in the stack 204. The number of layers depends on the desired number of channels members for the device 200. In some embodiments, the number of the channel layers 208 is between 2 and 10.

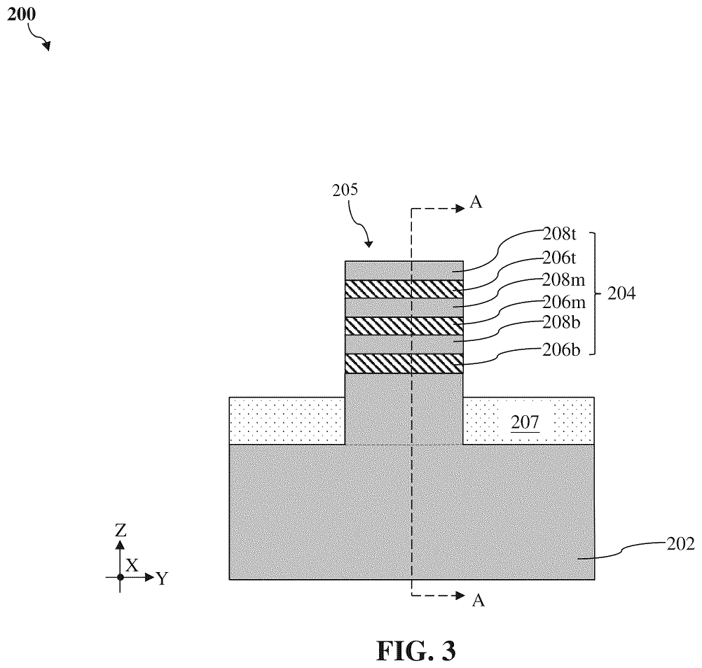

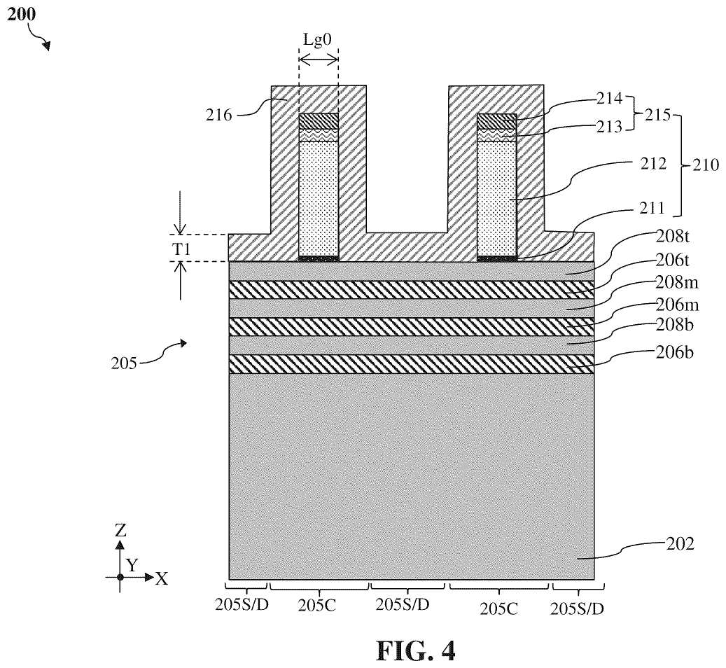

Referring to FIGS. 1 and 3-4, method 100 includes a block 104 where the stack 204 and a top portion of the substrate 202 are patterned to form a fin-shaped active region 205. As shown in FIG. 3, the fin-shaped active region 205 extends vertically along the Z direction from the substrate 202. The fin-shaped active region 205 includes a base portion formed from the substrate 202 and an upper portion formed from the stack 204. The fin-shaped active region 205 may be patterned using suitable processes including double-patterning or multi-patterning processes. FIG. 4 depicts a fragmentary cross-sectional view of the structure 200 taken along line A-A as shown in FIG. 3. As illustrated in FIGS. 3-4, the fin-shaped active region 205 extends lengthwise along the X direction.

After forming the fin-shaped active region 205, an isolation feature 207 (shown in FIG. 3) is formed adjacent to and around the base portion of the fin-shaped active region 205. The isolation feature 207 is disposed between the fin-shaped active region 205 and another fin-shaped active region 205. The isolation feature 207 may also be referred to as a shallow trench isolation (STI) feature 207. In some embodiments, the isolation feature 207 may include silicon oxide, silicon nitride, silicon oxynitride, fluorine-doped silicate glass (FSG), a low-k dielectric, combinations thereof, and/or other suitable materials. The formation of the isolation feature 207 may involve multiple processes such as deposition and etching. As shown in FIG. 3, the fin-shaped active region 205 rises above the isolation feature 207.

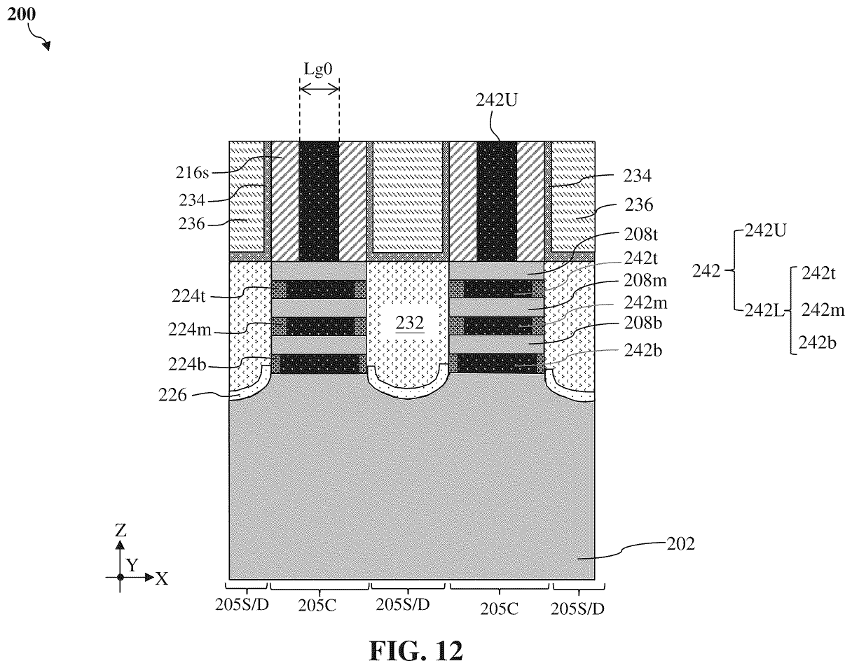

Referring to FIGS. 1 and 4, method 100 includes a block 106 where dummy gate stacks 210 are formed over channel regions 205C of the fin-shaped active region 205. The channel regions 205C and the dummy gate stacks 210 also define source/drain regions 205S/D that are not vertically overlapped by the dummy gate stacks 210. Each of the channel regions 205C is disposed between two source/drain regions 205S/D along the X direction. Two dummy gate stacks 210 are shown in FIG. 4 but the structure 200 may include more dummy gate stacks 210. In this embodiment, a gate replacement process (or gate-last process) is adopted where the dummy gate stacks 210 serve as placeholders for functional gate structures 242 (shown in FIG. 12). Other processes and configuration are possible. The dummy gate stack 210 includes a dummy dielectric layer 211, a dummy gate electrode layer 212 over the dummy dielectric layer 211, and a gate-top hard mask layer 215 over the dummy gate electrode layer 212. The dummy dielectric layer 211 may include silicon oxide. The dummy gate electrode layer 212 may include polysilicon. The gate-top hard mask layer 215 may be a multi-layer that includes a silicon oxide layer 213 and silicon nitride layer 214 formed on the silicon oxide layer 213. Suitable deposition process, photolithography and etching process may be employed to form the dummy gate stack 210. The dummy gate stack 210 has a gate length Lg0 along the X direction.

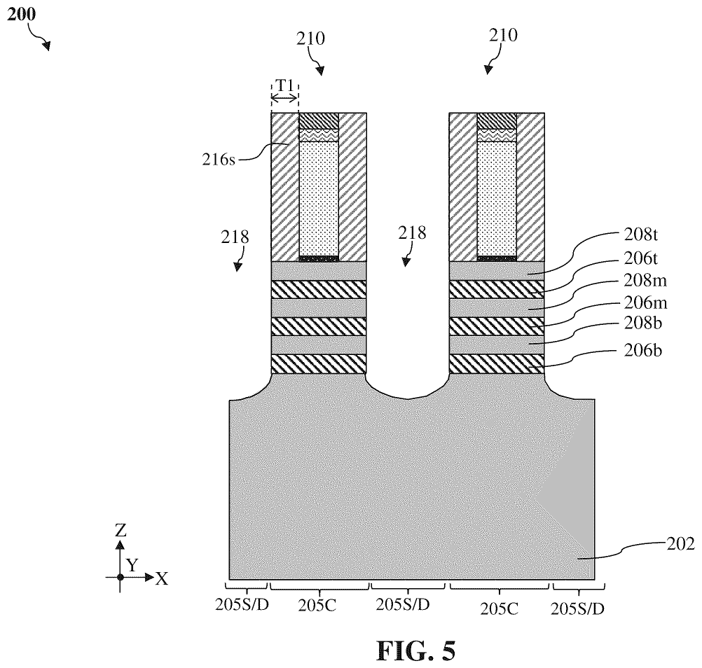

Referring to FIGS. 1 and 4-5, method 100 includes a block 108 where gate spacers 216s are formed to extend along sidewall surfaces of the dummy gate stacks 210. In an example process, the formation of the gate spacers 216s includes conformally depositing a single-layer or a multi-layer dielectric layer 216 (shown in FIG. 4) over the structure 200 and etching back of the dielectric layer 216 from top-facing surfaces of the structure 200 by an anisotropic etch process. The dielectric layer 216 is deposited using chemical vaper deposition (CVD), atomic layer deposition (ALD), or sub-atmospheric chemical vaper deposition (SACVD), and may include silicon oxide, silicon nitride, silicon carbide, silicon oxynitride, silicon carbonitride, silicon oxycarbide, silicon oxycarbonitride, and/or combinations thereof. The term “conformally” may be used herein for ease of description of a layer having a substantially uniform thickness over various regions. The dielectric layer 216 has a deposition thickness T1. That is, the gate spacer 216s spans a width that is equal to the deposition thickness T1 along the X direction. The profile of the gate spacer 216s shown in FIG. 5 is just an example and is not intended to be limiting. For example, in some embodiments, the gate spacer 216s may have a uniform width (e.g., T1) from bottom to top. In some other embodiments, the gate spacer 216s may have a non-uniform width from bottom to top, and a bottom surface of the gate spacer 216s spans a width T1.

Referring to FIGS. 1 and 5, method 100 includes a block 110 where source/drain regions 205S/D of the fin-shaped active region 205 are recessed to form source/drain openings 218. In some embodiments, the source/drain regions 205S/D of the fin-shaped active region 205 that are not covered by the dummy gate stacks 210 and the gate spacers 216s are anisotropically etched by a dry etch or a suitable etching process to form source/drain openings 218. An exemplary dry etching process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. The source/drain openings 218 extend through the stack 204 of channel layers 208 and sacrificial layers 206 and may partially extend into the substrate 202. As illustrated by FIG. 5, sidewalls of the channel layers 208 and the sacrificial layers 206 are exposed in the source/drain openings 218. In an embodiment, the source/drain openings 218 have substantially straight sidewalls. That is, sidewalls of the channel layers 208 and the sacrificial layers 206 exposed in the source/drain opening 218 are substantially vertically aligned.

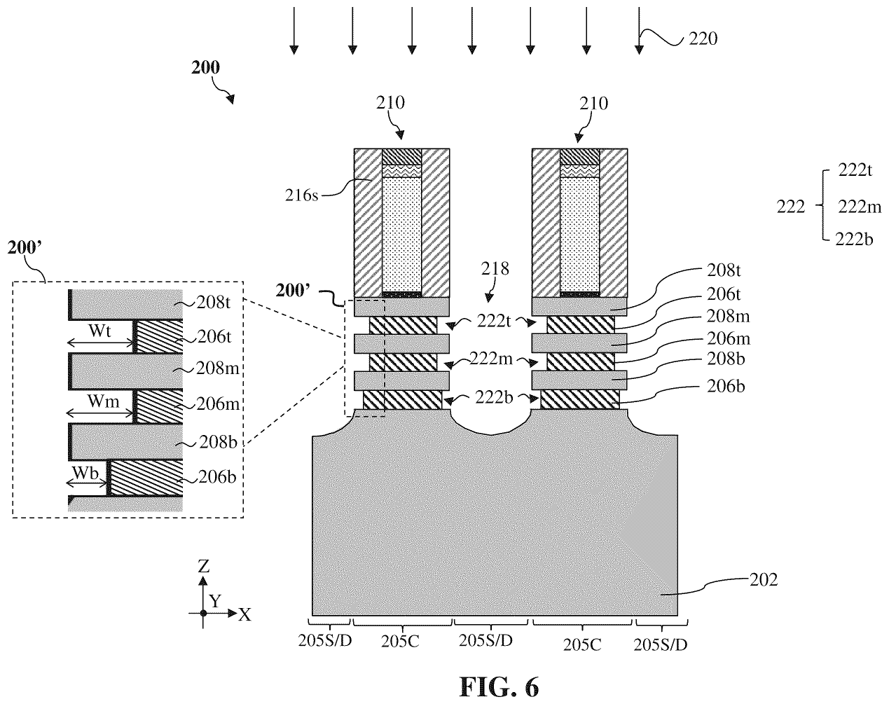

Referring to FIGS. 1 and 6, method 100 includes a block 112 where an etching process 220 is performed to selectively recess the sacrificial layers 206 to form inner spacer recesses 222. The etching process 220 selectively and partially recess the sacrificial layers 206 to form inner spacer recesses 222, while the exposed channel layers 208 are not significantly etched. In an embodiment where the channel layers 208 consist essentially of silicon (Si) and sacrificial layers 206 consist essentially of silicon germanium (SiGe), the etching process 220 that selectively and partially recesses the sacrificial layers 206 may include use of a selective isotropic etching process (e.g., a selective dry etching process or a selective wet etching process), and the extent at which the sacrificial layers 206 are recessed is controlled by duration of the etching process 220. In this embodiment, to form a gate structure having different gate lengths at different positions, an etchant is selected for the etching process 220 that etches silicon germanium layers having different germanium concentrations at different etch rates. More specifically, etchant of the etching process 220 etches a silicon germanium layer having a lower germanium concentration at a lower rate than it etches a silicon germanium layer having a higher germanium concentration. An example selective dry etching process of the etching process 220 may include use of one or more fluorine-based etchants, such as fluorine gas or hydrofluorocarbons. An example selective wet etching process of the etching process 220 may include an APM etch (e.g., ammonia hydroxide-hydrogen peroxide-water mixture).

In this illustrated example, the topmost sacrificial layer 206t has a germanium concentration Ct higher than a germanium concentration Cb of the bottommost sacrificial layer 206b, and the middle sacrificial layer 206m has a germanium concentration Cm higher than the germanium concentration of the bottommost sacrificial layer 206b. That is, the bottommost sacrificial layer 206b has the lowest germanium concentration among the sacrificial layers 206. Etchant of the etching process 220 thus etches the bottommost sacrificial layer 206b at a lower rate than it etches the topmost sacrificial layer 206t and the middle sacrificial layer 206m. The resulted inner spacer recesses 222 would thus span different widths along the X direction. An enlarged view of a portion 200′ of the structure 200 is illustrated. In this depicted example, the inner spacer recesses 222 include an inner spacer recess 222b formed from the selective and partial recess of the bottommost sacrificial layer 206b, an inner spacer recess 222m formed from the selective and partial recess of the middle sacrificial layer 206m, and an inner spacer recess 222t formed from the selective and partial recess of the topmost sacrificial layer 206t. The inner spacer recesses 222b, 222m, 222t may be collectively or individually referred to as inner spacer recesses 222. Due to germanium concentration relationships among the sacrificial layers 206 and the etch rate differences described above, the inner spacer recess 222b spans a width Wb less than a width Wm of the inner spacer recess 222m and less than a width Wt of the inner spacer recess 222t. In this embodiment, the germanium concentration Cb may be in a range between about 15 at % and 23 at %, the germanium concentration Cm and the germanium concentration Ct each may be in a range between about 25 at % and 30 at %. In an embodiment, the germanium concentration Ct is substantially equal to the germanium concentration Cm, and etchant of the etching process 220 etches the topmost sacrificial layer 206t and the middle sacrificial layer 206m at the same rate that is higher than it etches the bottommost sacrificial layer 206b. In an embodiment, the width Wm is equal to the width Wt and is greater than the width Wb.

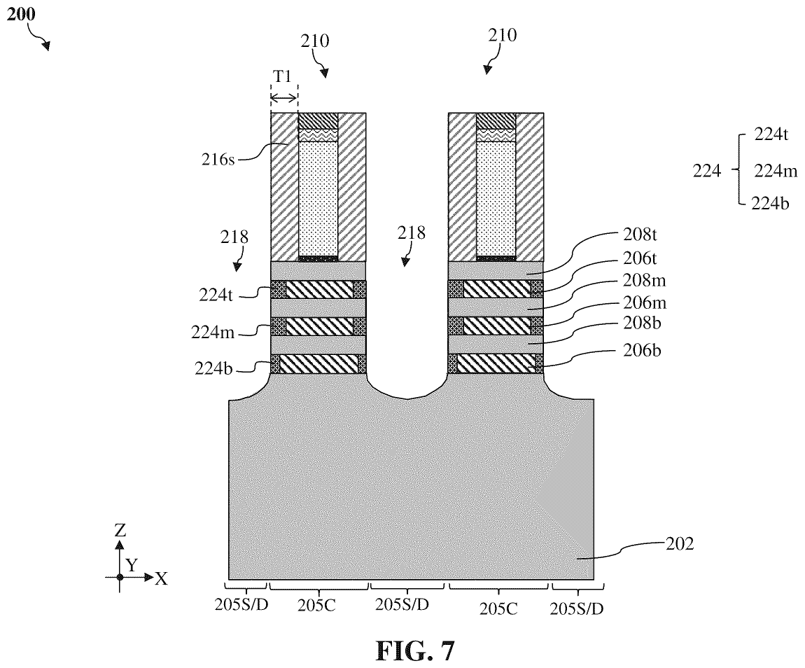

Referring to FIGS. 1 and 7, method 100 includes a block 114 where inner spacer features 224 are formed in the inner spacer recesses 222. After the formation of the inner spacer recesses 222, an inner spacer material layer is deposited over the structure 200, including in the inner spacer recesses 222. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excessive inner spacer material layer, thereby forming the inner spacer features 224. The etch back process at block 114 may be a dry etching process that is similar to the dry etching process used in the formation of the source/drain openings 218. In this illustrated example, the inner spacer features 224 includes an inner spacer feature 224b formed in the inner spacer recess 222b, an inner spacer feature 224m formed in the inner spacer recess 222m, and an inner spacer feature 224t formed in the inner spacer recess 222t. The inner spacer features 224b, 224m, and 224t may be collectively or individually referred to as the inner spacer features 224 or the inner spacer feature 224, respectively. The inner spacer features 224 track the shapes of the corresponding inner spacer recesses 222. That is, in this illustrated embodiment, the inner spacer feature 224b formed in the inner spacer recess 222b has a width substantially equal to the width Wb, the inner spacer feature 224m formed in the inner spacer recess 222m has a width substantially equal to the width Wm that is greater than Wb, and the inner spacer feature 224t formed in the inner spacer recess 222t has a width substantially equal to the width Wt that is greater than Wb. In some embodiments, a difference between the width Wm and the width Wt is greater than 1 nm. Each of the width Wb, width Wm, and the width Wt is less than the width T1 (shown in FIG. 5) of the gate spacer 216s. In other words, the gate spacer 216s overhangs each of the inner spacer features 224 and is vertically overlapped with the recessed sacrificial layers 206.

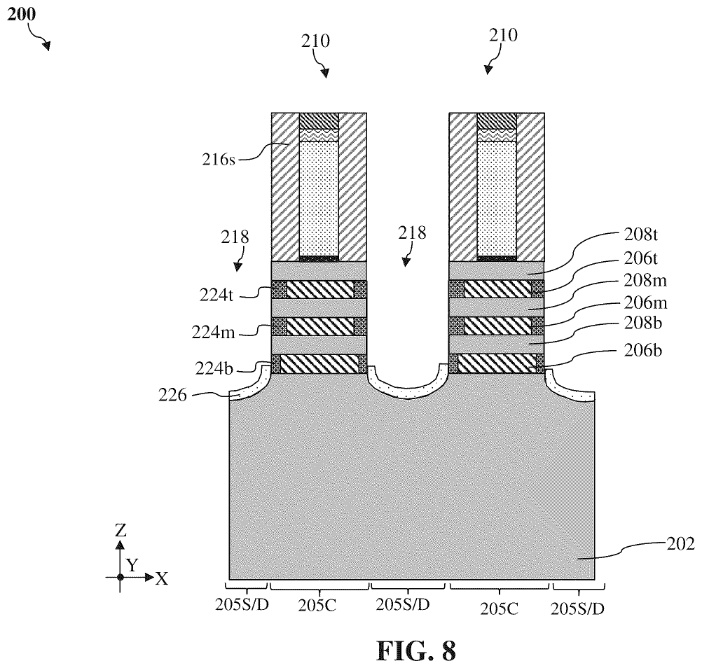

Referring to FIGS. 1 and 8, method 100 includes a block 116 where a dielectric layer 226 is formed in the source/drain openings 218 to reduce a parasitic capacitance of a final structure of the structure 200. In an example process, an insulation layer is deposited over the structure 200 by using a physical vaper deposition (PVD) process. Due to the properties of the PVD process, a portion of the insulation layer formed on a top or planar surface are thicker than a portion of insulation layer formed on a side surface. That is, the insulation layer includes a first portion formed over top surfaces of the dummy gate stacks 210, a second portion extending along exposed sidewall surfaces of the source/drain openings 218 and sidewall surfaces of the gate spacers 214a, and a third portion formed on the exposed top surface of the substrate 202. A thickness of the first portion and third portion are greater than a thickness of the second portion. Then, a combination of deposition, lithography, and etching processes are performed to remove the first portion and the second portion of the insulation layer, leaving at least a part of the third portion of the insulation layer in the source/drain openings 218, thereby forming the dielectric layer 226 in the source/drain openings 218. The top surface of the dielectric layer 226 may be above, coplanar with, or below the top surface of the bottommost inner spacer feature 224b of the inner spacer features 224. In an embodiment, the dielectric layer 226 has a uniform thickness and is less than a thickness of the bottommost inner spacer feature 224b of the inner spacer features 224. The dielectric layer 226 may include silicon nitride (SiN), silicon oxynitride (SiON), silicon oxycarbonitride (SiOCN), silicon oxycarbide (SiOC), silicon carbonitride (SiCN), aluminum oxide, hafnium oxide, or other suitable materials. In an embodiment, the dielectric layer 226 and the inner spacer features 224 have the same composition. It is noted that, in some embodiments, the structure 200 may be free of the dielectric layer 226.

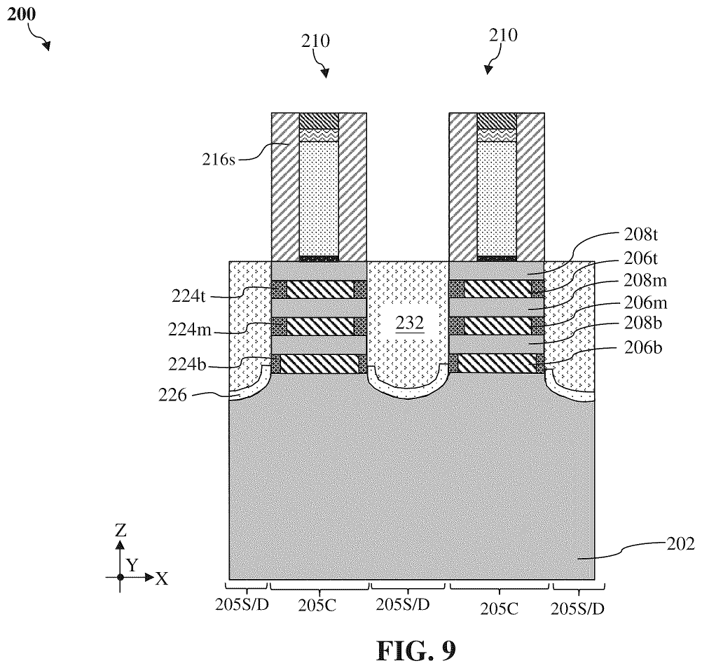

Referring to FIGS. 1 and 9, method 100 includes a block 118 where source/drain features 232 are formed in the source/drain openings 218. Source/drain feature(s) may refer to a source or a drain, individually or collectively dependent upon the context. The source/drain features 232 are coupled to the channel layers (e.g., channel layers 208t, 208m, 208b) of the channel regions 205C and each may be epitaxially and selectively formed from exposed semiconductor surfaces (e.g., sidewalls of the channel layers 208t, 208m, 208b) by using an epitaxial process, such as vapor phase epitaxy (VPE), ultrahigh vacuum chemical vapor deposition (UHV-CVD), molecular-beam epitaxy (MBE), and/or other suitable processes. Each of the source/drain features 232 may include N-type source/drain features and/or P-type source/drain features dependent upon types of transistors and varactors. Example N-type source/drain features may include silicon, phosphorus-doped silicon, arsenic-doped silicon, antimony-doped silicon, or other suitable material and may be in-situ doped during the epitaxial process by introducing an N-type dopant, such as phosphorus, arsenic, or antimony, or ex-situ doped using a junction implant process. Example P-type source/drain features may include germanium, gallium-doped silicon germanium, boron-doped silicon germanium, or other suitable material and may be in-situ doped during the epitaxial process by introducing a P-type dopant, such as boron or gallium, or ex-situ doped using a junction implant process. In some embodiments, each of the source/drain features 232 may include multiple semiconductor layers with different doping concentrations. For example, each of the source/drain features 232 may include a lightly doped semiconductor layer and a heavily doped semiconductor layer disposed over the lightly doped semiconductor layer.

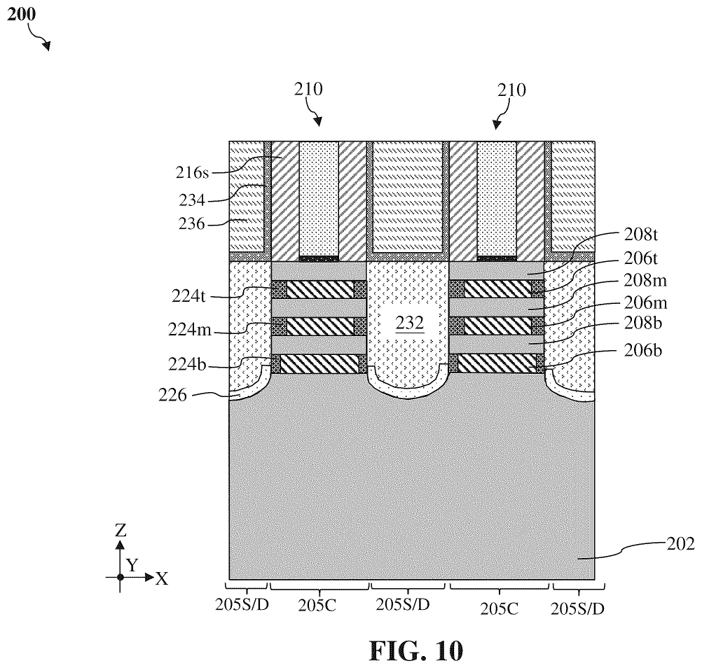

Referring to FIGS. 1 and 10, method 100 includes a block 120 where a contact etch stop layer (CESL) 234 and an interlayer dielectric (ILD) layer 236 are deposited over the structure 200. The CESL 234 may include silicon nitride, silicon oxynitride, and/or other materials known in the art and may be formed by ALD, plasma-enhanced chemical vapor deposition (PECVD) process and/or other suitable deposition or oxidation processes. As shown in FIG. 10, the CESL 234 may be deposited on top surfaces of the source/drain features 232, and sidewalls of the gate spacers 216s. The ILD layer 236 is deposited by a PECVD process or other suitable deposition technique over the structure 200 after the deposition of the CESL 234. The ILD layer 236 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the ILD layer 236, the structure 200 may be annealed to improve integrity of the ILD layer 236. A planarization process, such a chemical mechanical polishing (CMP) process may be performed to the structure 200 to remove excessive materials and expose the dummy gate electrode layer 212 in the dummy gate stacks 210.

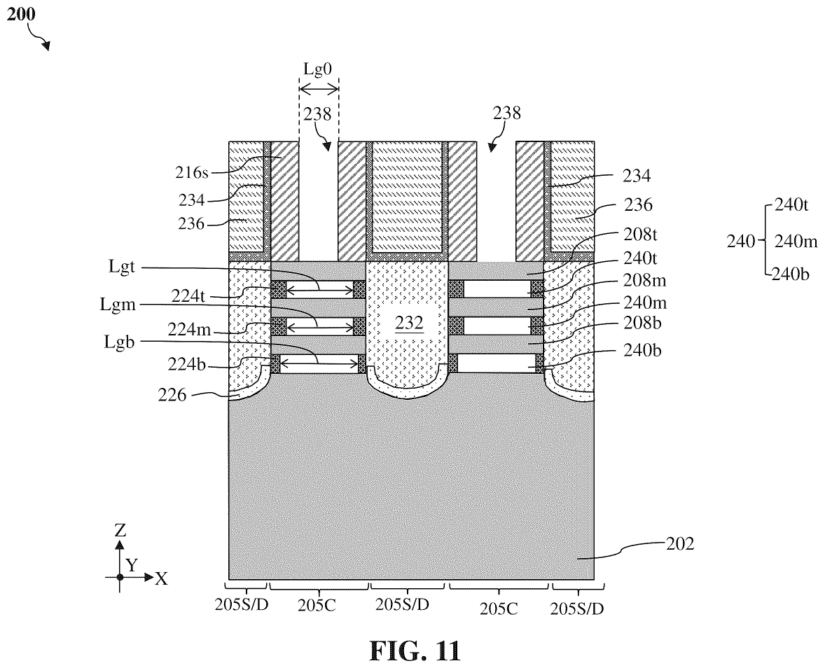

Referring to FIGS. 1 and 11, method 100 includes a block 122 where the dummy gate stacks 210 are selectively removed to form gate trenches 238. With the exposure of the dummy gate electrode layer 212, the dummy gate stacks 210 are selectively removed to form gate trenches 238. The removal of the dummy gate stacks 210 may include one or more etching process that are selective to the material in the dummy gate stacks 210. For example, the removal of the dummy gate stacks 210 may be performed using a selective wet etch, a selective dry etch, or a combination thereof. Each gate trench 238 spans a width substantially equal to the gate length Lg0 of the dummy gate stack 210.

Still referring to FIGS. 1 and 11, method 100 includes a block 124 where the sacrificial layers 206 are selectively removed to form gate openings 240. After the removal of the dummy gate stacks 210, the sacrificial layers 206 are selectively removed to release the channel layers 208 as channel members 208 in the channel regions 205C. The selective removal of the sacrificial layers 206 may be implemented by a selective dry etch, a selective wet etch, or other selective etching process. In some embodiments, the selective wet etching includes an APM etch (e.g., ammonia hydroxide-hydrogen peroxide-water mixture). The selectively removal of the sacrificial layers 206 forms gate openings. In this illustrated example, the selectively removal of the sacrificial layers 206b, 206m, and 206t forms gate openings 240b, 240m, and 240t, respectively. The gate openings 240b, 240m, and 240t may be collectively or individually referred to as the gate openings 240 or the gate opening 240. The gate opening 240t spans a length Lgt along the X direction, the gate opening 240m spans a length Lgm along the X direction, and the gate opening 240b spans a length Lgb along the X direction. The length of each of the gate openings 240 is an inverse function of a width of the corresponding inner spacer feature 224 exposed by the gate opening. In this embodiment, the length Lgb is greater than the length Lgt and the length Lgm. The length Lgt may be equal to, greater than, or less than the length Lgm. In this illustrated embodiment, the length Lgt is substantially equal to the length Lgm. Each of the length Lgt, the length Lgm, and the length Lgb is greater than the length Lg0. In some embodiments, a sum of the length Lgb and the width Wb is substantially equal to a sum of the length Lgm and the width Wm, which is substantially equal to a sum of length Lgt and the width Wt.

Referring to FIGS. 1 and 12, method 100 includes a block 126 where gate structures 242 are formed in the gate trenches 238 and gate openings 240 to wrap around and over the channel layers 208. Each of the gate structures 242 includes a gate dielectric layer (not separately labeled) and a gate electrode layer (not separately labeled) over the gate dielectric layer. In some embodiments, the gate dielectric layer includes an interfacial layer disposed on the channel members 208 and a high-k dielectric layer over the interfacial layer. Here, a high-k dielectric layer refers to a dielectric material having a dielectric constant greater than that of silicon dioxide, which is about 3.9. A low-k dielectric layer refers to a dielectric material having a dielectric constant no greater than that of silicon dioxide. In some embodiments, the interfacial layer includes silicon oxide. The high-k dielectric layer is then deposited over the interfacial layer using ALD, CVD, and/or other suitable methods. The high-k dielectric layer may include hafnium oxide. Alternatively, the high-k dielectric layer may include other high-k dielectrics, such as titanium oxide, hafnium zirconium oxide, tantalum oxide, hafnium silicon oxide, zirconium silicon oxide, lanthanum oxide, aluminum oxide, yttrium oxide, SrTiO₃, BaTiO₃, BaZrO, hafnium lanthanum oxide, lanthanum silicon oxide, aluminum silicon oxide, hafnium tantalum oxide, hafnium titanium oxide, (Ba,Sr)TiO₃ (BST), silicon nitride, silicon oxynitride, combinations thereof, or other suitable material. The gate electrode layer is then deposited over the gate dielectric layer using ALD, PVD, CVD, e-beam evaporation, or other suitable methods. The gate electrode layer may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride, titanium aluminum, titanium aluminum nitride, tantalum nitride, tantalum aluminum, tantalum aluminum nitride, tantalum aluminum carbide, tantalum carbonitride, aluminum, tungsten, nickel, titanium, ruthenium, cobalt, platinum, tantalum carbide, tantalum silicon nitride, copper, other refractory metals, or other suitable metal materials or a combination thereof. Further, where the structure 200 includes n-type transistors and p-type transistors, different gate electrode layers may be formed separately for n-type transistors and p-type transistors, which may include different work function metal layers (e.g., for providing different n-type and p-type work function metal layers).

The gate structure 242 includes an upper portion 242U formed in the gate trench 238 and a lower portion 242L formed under the upper portion 242U and in the gate openings 240. In this illustrated embodiment, the lower portion 242L includes a portion 242t formed in the gate opening 240t, a portion 242m formed in the gate opening 240m, and a portion 242b formed in the gate opening 240b. The upper portion 242U tracks the shape of the gate trench 238, and the portions 242t, 242m, and 242b track the shapes of the gate openings 240t, 240m, and 240b, respectively. In other words, the upper portion 242U has the gate length Lg0, the portions 242t, 242m, and 242b have gate lengths Lgt, Lgm, and Lgb, respectively. The gate length Lg0 is less than each of the gate lengths Lgt, Lgm, and Lgb, and the gate length Lgb is greater than the gate length Lgm and the gate length Lgt. In an embodiment, a height (along the Z direction) of each of the inner spacer features 224 is less than a height (along the Z direction) of the gate spacer 216s in the final structure of the structure 200. By forming the gate structure 242 having multiple gate lengths, the device performance may be adjusted. In this illustrated embodiment, the bottommost portion 242b of the gate structure 242 has the longest gate length. As a result, compared to existing technologies where all portions of the lower portion 242L have a same gate length that is less than the gate length Lgb, the extension resistance Rₑₓₜ associated with the bottommost channel member 208b is reduced. Thus, drive current associated with the bottommost channel member 208b may be improved. In addition, the gate spacer 216s has a width T1 greater than the inner spacer features 224, the upper portion 202U has a gate length Lg0 that is less than the gate length Lgm. As a result, a parasitic capacitance between the upper portion 242U of the gate structure 242 and its adjacent features (e.g., source/drain contacts formed directly over the source/drain feature 232) may be reduced.

Referring to FIG. 1, method 100 includes a block 128 where further processes are performed. For example, such further processes may form various contacts/vias, metal lines, power rails, as well as other multilayer interconnect features, such as ILD layers and/or etch stop layer (ESLs) over and/or under the structure 200, configured to connect the various features to form a functional circuit that includes the different semiconductor devices.

In the above embodiments, the germanium concentration Cb is less than the germanium concentration Cm and the germanium concentration Ct, and the gate length Lgb is greater than the gate length Lgm and the gate length Lgt. Other relationships among the gate lengths Lgb, Lgm, and Lgt are also possible. FIG. 13 depicts a fragmentary cross-sectional view of a first alternative structure 200A. The first alternative structure 200A is similar to the structure 200, and one of the differences between the structure 200A and the structure 200 includes that, as represented by FIG. 13, the gate length Lgb of the portion 242b is greater than the gate length Lgt of the portion 242t and is less than the gate length Lgm of the portion 242m. The gate length Lg0 is less than each of the gate lengths Lgt, Lgm, and Lgb. Another one of the differences between the structure 200A and the structure 200 includes that, the width Wb of the inner spacer feature 224b is greater than width Wm of the inner spacer feature 224m and is less than the width Wt of the inner spacer feature 224t. The width T1 of the gate spacer 216s is greater than each of the widths Wt, Wm, and Wb. Those relationships among the gate lengths Lgb, Lgm, and Lgt may be achieved by adjusting the germanium concentrations of the sacrificial layers 206. More specifically, in an embodiment, the germanium concentration Cb is greater than the germanium concentration Cm and is less than the germanium concentration Ct. In some other embodiments, the gate length Lgb of the portion 242b may be equal to the gate length Lgm of the portion 242m and is greater than the gate length Lgt of the portion 242t; and the width Wb of the inner spacer feature 224b may be equal to the width Wm of the inner spacer feature 224m and is less than the width Wt of the inner spacer feature 224t. In such embodiments, the germanium concentration Cb is equal to the germanium concentration Cm and is less than the germanium concentration Ct.

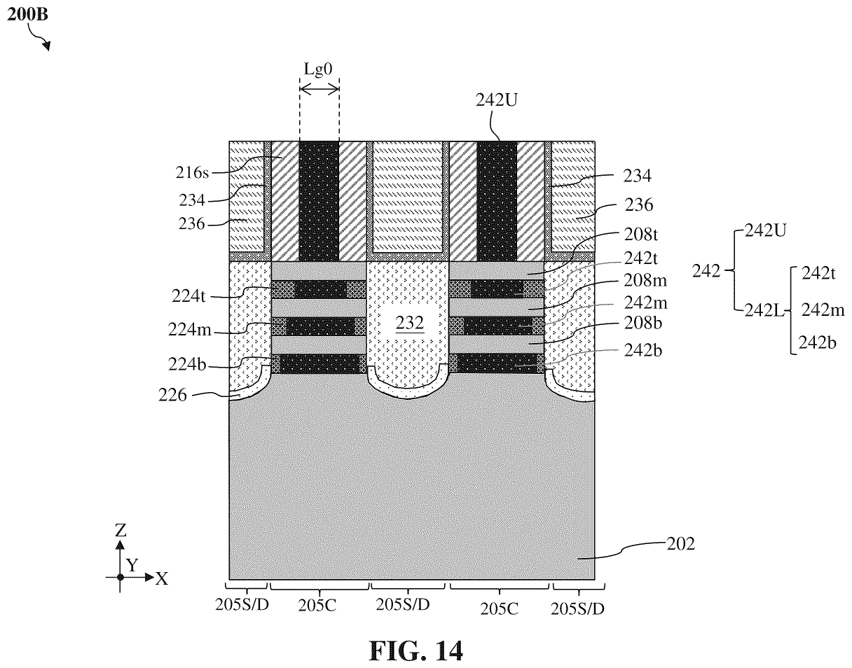

FIG. 14 depicts a fragmentary cross-sectional view of a second alternative structure 200B. The second alternative structure 200B is similar to the structure 200, and one of the differences between the structure 200B and the structure 200 includes that, as represented by FIG. 14, the gate length Lgb of the portion 242b is greater than the gate length Lgm of the portion 242m, and the gate length Lgm of the portion 242m is greater than the gate length Lgt of the portion 242t. The gate length Lg0 is less than each of the gate lengths Lgt, Lgm, and Lgb. The width Wb of the inner spacer feature 224b is less than the width Wm of the inner spacer feature 224m, and the width Wm of the inner spacer feature 224m is less than the width Wt of the inner spacer feature 224t. The width T1 of the gate spacer 216s is greater than each of the widths Wt, Wm, and Wb to facilitate parasitic capacitance reduction of the final structure of the structure 200. Those relationships may be achieved by adjusting the germanium concentrations of the sacrificial layers 206. More specifically, in an embodiment, the germanium concentration Cb is greater than the germanium concentration Cm, and the germanium concentration Cm is greater than the germanium concentration Ct.

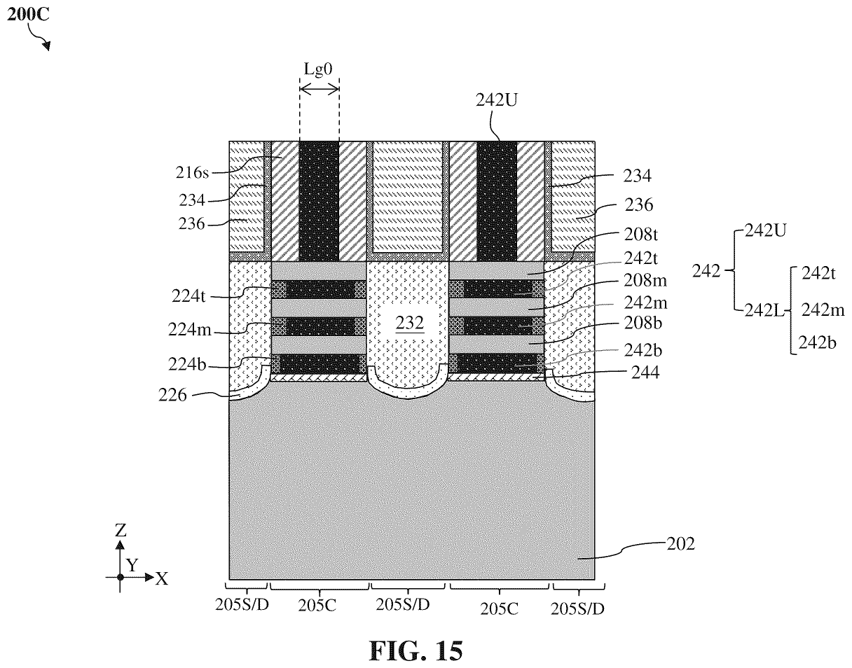

In the above embodiments described with reference to FIGS. 1-14, the bottommost portion (e.g., the portion 242b) of the gate structure 242 is in direct contact with the substrate 202. FIG. 15 depicts a fragmentary cross-sectional view of a third alternative structure 200C. The third alternative structure 200C is similar to the structure 200, and one of the differences between the structure 200C and the structure 200 includes that, as represented by FIG. 15, to further reduce parasitic capacitance of the structure 200, a dielectric layer 244 is formed between the bottommost portion (e.g., the portion 242b) of the gate structure 242 and the substrate 202. A bottommost surface of the gate structure 242 and a bottommost surface of the inner spacer features 224 are in direct contact with a top surface of the dielectric layer 244. A thickness of the dielectric layer 244 may be in a range between about 1 nm and about 10 nm. In some embodiments, the dielectric layer 244 may include silicon oxide, silicon nitride, silicon oxycarbide, silicon oxycarbonitride, silicon carbonitride, metal nitride, or a suitable dielectric material. A composition of the dielectric layer 244 may be the same as a composition of the inner spacer features 224. It is understood that the dielectric layer 244 may also be formed to facilitate the parasitic capacitance reduction of other structures (e.g., structures 200A, 200B, 200D, and 200E).

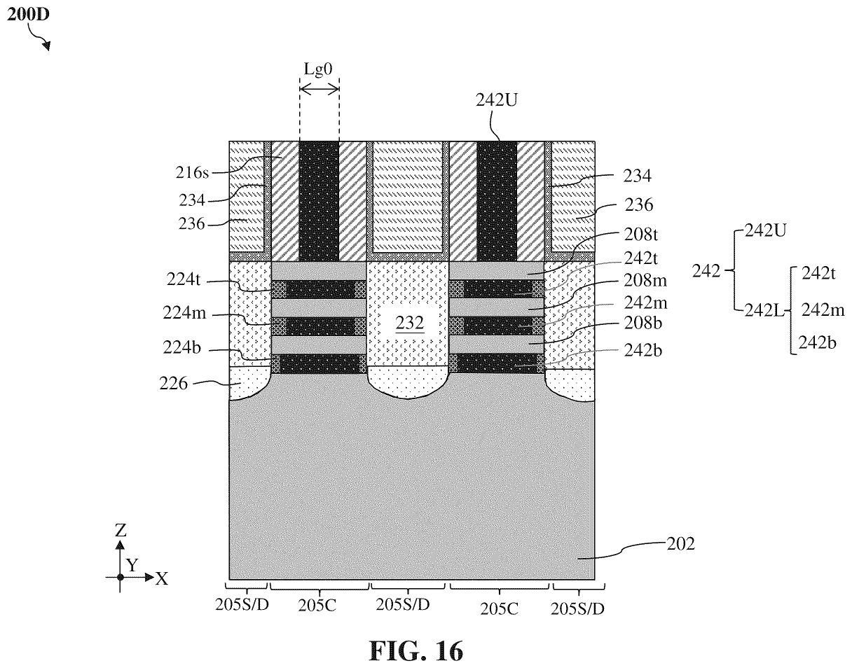

In the above embodiments described with reference to FIGS. 1-15, the dielectric layer 226 has a concave top surface and a substantially uniform thickness. In some other alternative embodiments, the dielectric layer 226 may have different profiles and configurations. FIG. 16 depicts a fragmentary cross-sectional view of a fourth alternative structure 200D. The fourth alternative structure 200D is similar to the structure 200, and one of the differences between the structure 200D and the structure 200 includes that, as represented by FIG. 16, the dielectric layer 226 in this embodiment substantially fills a lower portion of the source/drain opening 218 and has a substantially planar top surface. That is, a volume of the dielectric layer 226 of the fourth alternative structure 200D may be greater than a volume of the dielectric layer 226 of the structure 200. It is understood that the dielectric layer 226 of structure 200D shown in FIG. 16 may replace the dielectric layer 226 of other structures (e.g., structures 200A, 200B, and 200C).

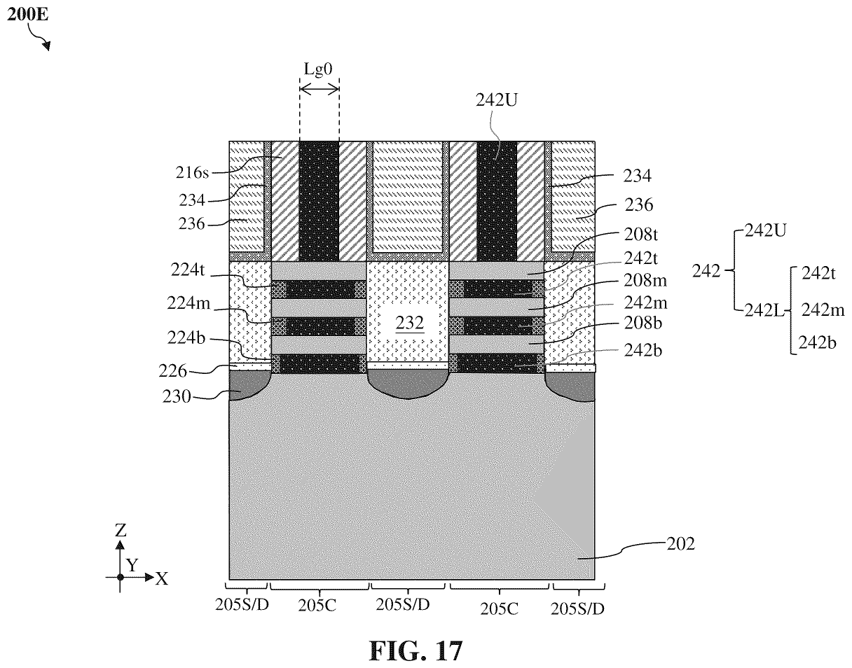

FIG. 17 depicts a fragmentary cross-sectional view of a fifth alternative structure 200E. The fifth alternative structure 200E is similar to the structure 200, and one of the differences between the structure 200E and the structure 200 includes that, as represented by FIG. 17, the structure 200E further includes a semiconductor layer 230 formed in the source/drain opening 218. The dielectric layer 226 is disposed between the source/drain feature 232 and the semiconductor layer 230. The semiconductor layer 230 may be undoped or not intentionally doped and may be formed by using an epitaxial process. In some embodiments, the semiconductor layer 230 may include undoped silicon (Si), undoped germanium (Ge), undoped silicon germanium (SiGe), or other suitable materials. In an embodiment, the semiconductor layer 230 includes undoped silicon (Si).

Embodiments of the present disclosure provide advantages. Methods of the present disclosure provides mechanisms of individually and flexibly adjusting the gate lengths of different portions of a gate structure of a GAA transistor and individually and flexibly adjusting the widths of inner spacer features, thereby reducing parasitic resistance and improving device performance. The mechanisms may include provide sacrificial layers having different compositions (e.g., different germanium concentration) such that etchant may etch those sacrificial layers at different rates. In some embodiments, parasitic capacitance of the GAA transistor may also be reduced. Additionally, the processes of the present disclosure are compatible with existing fabrication process flow.

The present disclosure provides for many different embodiments. Semiconductor structures and methods of fabrication thereof are disclosed herein. In one exemplary aspect, the present disclosure is directed to a method. The method includes receiving a structure comprising a fin-shaped active region over a substrate and comprising a plurality of channel layers interleaved by a plurality of sacrificial layers and a dummy gate stack over a channel region of the fin-shaped active region, removing a source/drain region of the fin-shaped active region to form a source/drain opening, performing an etching process to selectively recess the plurality of sacrificial layers to form inner spacer recesses, forming inner spacer features in the inner spacer recesses, forming a source/drain feature in the source/drain opening, selectively removing the dummy gate stack to form a gate trench, selectively removing the plurality of sacrificial layers to form a plurality of gate openings, and forming a gate structure in the gate trench and the plurality of gate openings, wherein the gate structure comprises a first portion formed in a first gate opening of the plurality of gate openings and a second portion formed in a second gate opening of the plurality of gate openings, a gate length of the first portion is different from a gate length of the second portion.

In some embodiments, a gate length of a portion of the gate structure formed in the gate trench may be less than the gate length of the first portion. In some embodiments, the first gate opening is disposed under the second gate opening, and the gate length of the first portion is greater than the gate length of the second portion. In some embodiments, the plurality of sacrificial layers may include a bottommost sacrificial layer and a topmost sacrificial layer over the bottommost sacrificial layer, and a germanium concentration of the topmost sacrificial layer is different than a germanium concentration of the bottommost sacrificial layer. In some embodiments, etchant of the etching process etches the topmost sacrificial layer at a rate higher than it etches the bottommost sacrificial layer. In some embodiments, the selectively removing of the bottommost sacrificial layer and the topmost sacrificial layer of the plurality of sacrificial layers forms the first gate opening and the second gate opening respectively, and the second gate opening spans a width greater than the first gate opening. In some embodiments, the structure may also include a gate spacer extending along a sidewall surface of the dummy gate stack, a width of the gate spacer is greater than a width of a widest inner spacer feature of the inner spacer features. In some embodiments, the method may also include, before the forming of the source/drain feature, forming a dielectric layer to fill a bottom portion of the source/drain opening, wherein the source/drain feature is over and in direct contact with the dielectric layer. In some embodiments, the method may also include forming a dielectric layer between and in direct with the substrate and the gate structure.

In another exemplary aspect, the present disclosure is directed to a method. The method includes forming a first sacrificial layer over a substrate, forming a first channel layer over the first sacrificial layer, forming a second sacrificial layer over the first channel layer, wherein the first sacrificial layer and the second sacrificial layer comprise different compositions, forming a second channel layer over the second sacrificial layer, performing a first etching process to laterally recess the first sacrificial layer and the second sacrificial layer at different etch rates, after the performing of the first etching process, performing a second etching process to selectively remove the laterally recessed first sacrificial layer and the second sacrificial layer to form a first gate opening and a second gate opening, and forming a gate structure in the first gate opening and the second gate opening. In some embodiments, the first sacrificial layer and the second sacrificial layer may include silicon germanium, and a germanium concentration of the second sacrificial layer may be higher than a germanium concentration of the first sacrificial layer. In some embodiments, a gate length of a portion of the gate structure formed in the first gate opening may be greater than a gate length of a portion of the gate structure formed in the second gate opening. In some embodiments, the gate structure may also include a top portion formed over the second channel layer, a gate length of the top portion of the gate structure is less than the gate length of the portion of the gate structure formed in the second gate opening. In some embodiments, the method may also include forming a third sacrificial layer over the second channel layer, wherein the first sacrificial layer and the third sacrificial layer comprise a same material but different constituent atomic percentages, and forming a third channel layer over the third sacrificial layer, where the performing of the first etching process further laterally recesses the third sacrificial layer, the performing of the second etching process further selectively removes the laterally recessed third sacrificial layer, thereby forming a third gate opening, the gate structure is further formed in the third gate opening. In some embodiments, a germanium concentration of the third sacrificial layer may be higher than a germanium concentration of the first sacrificial layer. In some embodiments, a germanium concentration of the third sacrificial layer may be higher than a germanium concentration of the second sacrificial layer.

In yet another exemplary aspect, the present disclosure is directed to a semiconductor structure. The semiconductor structure includes a plurality of nanostructures over a substrate, a source/drain feature coupled to the plurality of nanostructures, and a gate structure wrapping around and over each of the plurality of nanostructures and including a first portion disposed under a topmost nanostructure of the plurality of nanostructures and having a first gate length, and a second portion disposed between the substrate and a bottommost nanostructure of the plurality of nanostructures and having a second gate length greater than the first gate length.

In some embodiments, the gate structure may also include a top portion over the topmost nanostructure of the plurality of nanostructures and having a gate length less than the first gate length. In some embodiments, the semiconductor device may also include a gate spacer disposed adjacent to the top portion of the gate structure and extending over the first portion and second portion of the gate structure. In some embodiments, semiconductor device may also include a plurality of inner spacer features interleaving the plurality of nanostructures, where a bottommost inner spacer feature of the plurality of inner spacer features has a width less than other inner spacer features of the plurality of inner spacer features.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a structure comprising:
a fin-shaped active region over a substrate and comprising a plurality of channel layers interleaved by a plurality of sacrificial layers, and
a dummy gate stack over a channel region of the fin-shaped active region,
removing a source/drain region of the fin-shaped active region to form a source/drain opening;
performing an etching process to selectively recess the plurality of sacrificial layers to form inner spacer recesses;
forming inner spacer features in the inner spacer recesses;
forming a source/drain feature in the source/drain opening;
selectively removing the dummy gate stack to form a gate trench;
selectively removing the plurality of sacrificial layers to form a plurality of gate openings; and
forming a gate structure in the gate trench and the plurality of gate openings, wherein the gate structure comprises a first portion formed in a first gate opening of the plurality of gate openings and a second portion formed in a second gate opening of the plurality of gate openings, a gate length of the first portion is different from a gate length of the second portion.

2. The method of claim 1, wherein a gate length of a portion of the gate structure formed in the gate trench is less than the gate length of the first portion.

3. The method of claim 1, wherein the first gate opening is disposed under the second gate opening, and the gate length of the first portion is greater than the gate length of the second portion.

4. The method of claim 1, wherein the plurality of sacrificial layers comprise a bottommost sacrificial layer and a topmost sacrificial layer over the bottommost sacrificial layer, and a germanium concentration of the topmost sacrificial layer is different than a germanium concentration of the bottommost sacrificial layer.

5. The method of claim 4, wherein etchant of the etching process etches the topmost sacrificial layer at a rate higher than it etches the bottommost sacrificial layer.

6. The method of claim 4, wherein the selectively removing of the bottommost sacrificial layer and the topmost sacrificial layer of the plurality of sacrificial layers forms the first gate opening and the second gate opening respectively, and the second gate opening spans a width greater than the first gate opening.

7. The method of claim 1, wherein the structure further comprises a gate spacer extending along a sidewall surface of the dummy gate stack, wherein a width of the gate spacer is greater than a width of a widest inner spacer feature of the inner spacer features.

8. The method of claim 1, further comprising:
before the forming of the source/drain feature, forming a dielectric layer to fill a bottom portion of the source/drain opening, wherein the source/drain feature is over and in direct contact with the dielectric layer.

9. The method of claim 1, further comprising:
forming a dielectric layer between and in direct with the substrate and the gate structure.

10. A method, comprising:
forming a first sacrificial layer over a substrate;
forming a first channel layer over the first sacrificial layer;
forming a second sacrificial layer over the first channel layer, wherein the first sacrificial layer and the second sacrificial layer comprise different compositions;
forming a second channel layer over the second sacrificial layer;
performing a first etching process to laterally recess the first sacrificial layer and the second sacrificial layer at different etch rates;
after the performing of the first etching process, performing a second etching process to selectively remove the laterally recessed first sacrificial layer and the second sacrificial layer to form a first gate opening and a second gate opening; and
forming a gate structure in the first gate opening and the second gate opening.

11. The method of claim 10, wherein the first sacrificial layer and the second sacrificial layer comprise silicon germanium, and a germanium concentration of the second sacrificial layer is higher than a germanium concentration of the first sacrificial layer.

12. The method of claim 11, wherein a gate length of a portion of the gate structure formed in the first gate opening is greater than a gate length of a portion of the gate structure formed in the second gate opening.

13. The method of claim 12, wherein the gate structure further comprises a top portion formed over the second channel layer, a gate length of the top portion of the gate structure is less than the gate length of the portion of the gate structure formed in the second gate opening.

14. The method of claim 10, further comprising:
forming a third sacrificial layer over the second channel layer, wherein the first sacrificial layer and the third sacrificial layer comprise a same material but different constituent atomic percentages; and
forming a third channel layer over the third sacrificial layer,
wherein the performing of the first etching process further laterally recesses the third sacrificial layer,
wherein the performing of the second etching process further selectively removes the laterally recessed third sacrificial layer, thereby forming a third gate opening,
wherein the gate structure is further formed in the third gate opening.

15. The method of claim 14, wherein a germanium concentration of the third sacrificial layer is higher than a germanium concentration of the first sacrificial layer.

16. The method of claim 14, wherein a germanium concentration of the third sacrificial layer is higher than a germanium concentration of the second sacrificial layer.

17. A semiconductor device, comprising:
a plurality of nanostructures over a substrate;
a source/drain feature coupled to the plurality of nanostructures; and
a gate structure wrapping around and over each of the plurality of nanostructures, wherein the gate structure comprises:
a first portion disposed under a topmost nanostructure of the plurality of nanostructures and having a first gate length, and
a second portion disposed between the substrate and a bottommost nanostructure of the plurality of nanostructures and having a second gate length greater than the first gate length.

18. The semiconductor device of claim 17, wherein the gate structure further comprises a top portion over the topmost nanostructure of the plurality of nanostructures and having a gate length less than the first gate length.

19. The semiconductor device of claim 18, further comprising:
a gate spacer disposed adjacent to the top portion of the gate structure,
wherein the gate spacer extends over the first portion and second portion of the gate structure.

20. The semiconductor device of claim 18, further comprising:
a plurality of inner spacer features interleaving the plurality of nanostructures,
wherein a bottommost inner spacer feature of the plurality of inner spacer features has a width less than other inner spacer features of the plurality of inner spacer features.
